(19) United States
(12) Patent Application Publication
(10) Pub. No.: US 2012/0261767 A1
(43) Pub. Date: Oct. 18, 2012

(54) METHOD AND STRUCTURE FOR REDUCING GATE LEAKAGE CURRENT AND POSITIVE BIAS TEMPERATURE INSTABILITY DRIFT

(75) Inventor: Michael D. Church, Canyon Lake, FL (US)

(73) Assignee: INTERSIL AMERICAS INC., Milpitas, CA (US)

(21) Appl. No.: 13/423,841

(22) Filed: Mar. 19, 2012

Related U.S. Application Data
(60) Provisional application No. 61/475,463, filed on Apr. 14, 2011.

(51) Int. Cl. H01L 27/088; H01L 27/02; H01L 21/3105; H01L 21/314; H01L 21/311

(52) U.S. Cl. 257/392; 438/763; 438/694; 438/759; 257/499; 257/E27.06; 257/E27.009; 257/E21.267; 257/E21.251; 257/E21.241

(57) ABSTRACT

Systems and methods for reducing gate leakage current and positive bias temperature instability drift are provided. In one embodiment, a system comprises a p-channel field effect transistor (PFET) device on a semiconductor substrate, and a high voltage transistor on the substrate. The system also comprises a plurality of silicides formed in the substrate, the plurality of silicides formed proximate to the PFET device and the high voltage transistor. Further, the system comprises a buffer oxide layer formed over the substrate, the PFET device, and the high voltage transistor and a moisture barrier formed over the buffer layer, the moisture barrier comprised of silicon oxynitride. Additionally, the system comprises an interlayer dielectric device formed over the moisture barrier and a plurality of electrical contacts extending through the interlayer dielectric, the moisture barrier, and the buffer oxide layer, wherein the plurality of electrical contacts are electrically connected to the plurality of silicides.

### CROSS REFERENCE TO RELATED APPLICATIONS

This application claims the benefit of priority to U.S. Provisional Application No. 61/475,463, filed on Apr. 14, 2011, the disclosure of which is incorporated herein by reference.

### DRAWINGS

Understanding that the drawings depict only exemplary embodiments and are not therefore to be considered limiting in scope, the exemplary embodiments will be described with additional specificity and detail through the use of the accompanying drawings, in which:

FIG. 1 is a cross sectional view of a semiconductor device having a p-channel metal oxide semiconductor (PMOS) transistor and a high voltage transistor constructed according to one embodiment of the present invention.

FIGS. 2A-2D are block diagrams illustrating the fabrication of a structure for reducing high voltage gate leakage and PMOS positive bias temperature instability drift (PBTI) according to one embodiment of the present invention.

FIGS. 3A-3B are graphs that illustrate the effects of a moisture barrier according to one embodiment of the present invention.

FIG. 4 is a block diagram of an embodiment of an electronic system with a power converter that includes PMOS and high voltage transistors having a moisture barrier and a buffer oxide layer.

FIG. 5 is a flow diagram for a method for simultaneously reducing high voltage gate leakage and PMOS positive bias temperature instability drift according to one embodiment of the present invention.

In accordance with common practice, the various described features are not drawn to scale but are drawn to emphasize specific features relevant to the exemplary embodiments.

### DETAILED DESCRIPTION

In the following detailed description, reference is made to the accompanying drawings that form a part hereof, and in which is shown by way of illustration, specific illustrative embodiments. However, it is to be understood that other embodiments may be utilized and that logical, mechanical, and electrical changes may be made. Furthermore, the method presented in the drawing figures and the specification is not to be construed as limiting the order in which the individual steps may be performed. The following detailed description is, therefore, not to be taken in a limiting sense.

Two interrelated problems have been discovered in semiconductor devices that include a PMOS transistor and a high voltage transistor on the same semiconductor substrate, where the PMOS transistor and high voltage transistor are electrical devices that differ from one another in at least one characteristic. For example, in one embodiment, the PMOS transistor is used for amplifying or switching electronic signals. The high voltage transistor characteristically differs from the PMOS transistor in that it is designed to handle higher voltages. The first problem that affects the above described semiconductor devices is that at high temperatures, if the gate of the PMOS transistor is biased more positive than the source and body, the threshold voltage can drift when subjected to stress caused by a bias voltage. This is referred to as positive bias temperature instability (PBTI) drift. The second problem was discovered in attempts to address PBTI in PMOS transistors. The second problem is that attempts to decrease PBTI cause unacceptable levels of gate leakage in high voltage transistors that are on the same substrate as the PMOS transistors.

The embodiments described below provide a process solution which simultaneously reduces (or eliminates) PBTI in PMOS transistors and reduces gate leakage current in high voltage transistors with a thick gate oxide. In all other respects, the PMOS transistors and the high voltage transistors are fabricated using conventional process flows.

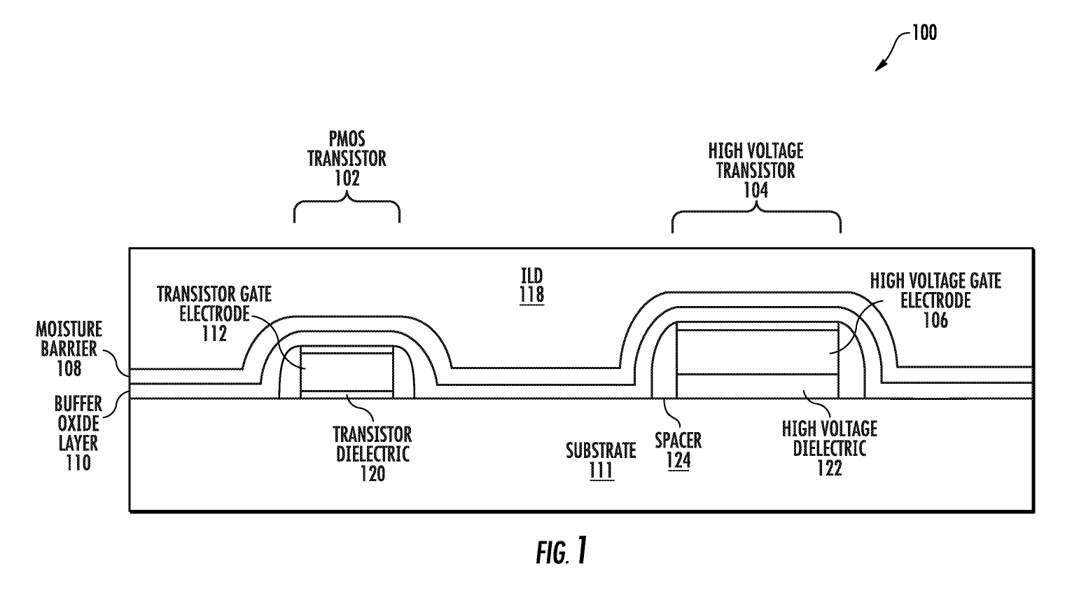

FIG. 1 is a cross sectional view of a semiconductor circuit 100 having two electronic devices formed on a substrate 111. The electronic devices differ from one another in at least one characteristic. For example, semiconductor circuit 100 has a PMOS transistor 102 and a high voltage transistor 104 formed on a semiconductor substrate 111 according to one embodiment of the present disclosure.

In certain embodiments, transistor 102 is a field effect transistor (FET) such as a p-channel metal oxide semiconductor (PMOS) transistor. For example, in at least one embodiment, transistor 102 is a traditional 2.5V or 5V device using 0.25 μm technology. Transistor 102 includes a transistor gate electrode 112 and a transistor dielectric 120 formed on semiconductor substrate 111. In certain implementations, transistor gate electrode 112 is a polysilicon electrode for transistor 102. Further, transistor dielectric 120 is formed on substrate 111 to support the operation of transistor gate electrode 112. To support the operation of transistor gate electrode 112, transistor dielectric 120 is sufficiently thick to support the voltages that are applied to transistor gate electrode 112, e.g., 2.5V or 5V.

As described above, semiconductor circuit 100 also includes a high voltage transistor 104. In certain embodiments, high voltage transistor 104 is a complementary metal oxide semiconductor (CMOS) device having a high voltage gate electrode 106. In a manner similar to transistor 102, high voltage transistor 104 also includes a high voltage dielectric 122. High voltage dielectric 122 functions in a similar manner to transistor dielectric 120. However, since high voltage dielectric 122 supports the high voltage operation of high voltage transistor 104, high voltage dielectric 122 is thicker than PMOS transistor dielectric 120. For example, in certain implementations, high voltage transistor 104 is a 40V device. When high voltage transistor 104 is a 40V device, the high voltage dielectric may have a thickness of 1000-1100 angstroms. In certain exemplary embodiments, both high voltage transistor 104 and PMOS transistor 102 are formed with spacers 124. Spacers 124 are used to offset silicides from transistor gate electrode 112 and high voltage gate electrode 106.

To address the problems of PBTI drift and gate leakage mentioned above, the semiconductor circuit 100 includes two new layers. First, to address the PBTI drift, the semiconductor circuit 100 includes a moisture barrier 108. Moisture barrier 108 is a layer that prevents moisture introduced during fabrication operations that occur after the deposition of moisture barrier 108 from passing through the moisture barrier 108, thus protecting the encapsulated semiconductor devices from moisture. In one embodiment, moisture barrier 108 comprises a layer of silicon oxynitride (SiON). In some implementations, moisture barrier 108 has a depth thickness of approximately 400 angstroms. In some embodiments, the addition of a moisture barrier 108 adversely increases the high voltage gate leakage. To address the problem of high voltage gate leakage current in high voltage transistor 104, a buffer oxide layer 110 is disposed over the semiconductor wafer below moisture barrier 108. Buffer oxide layer 110 is an intermediary layer designed to relieve stress introduced by the moisture barrier 108 thereby reducing leakage current in the high voltage devices. In certain implementations, buffer oxide layer 110 is a layer of silicon dioxide. Further, in at least one embodiment, buffer oxide layer 110 is a layer of silicon dioxide having a thickness of approximately 600 angstroms. Also, semiconductor circuit 100 includes an interlevel dielectric (ILD) layer 118 to isolate PMOS transistor gate electrode 112 and high voltage gate electrode 106 from metallization layers that are deposited on top of semiconductor device 100.

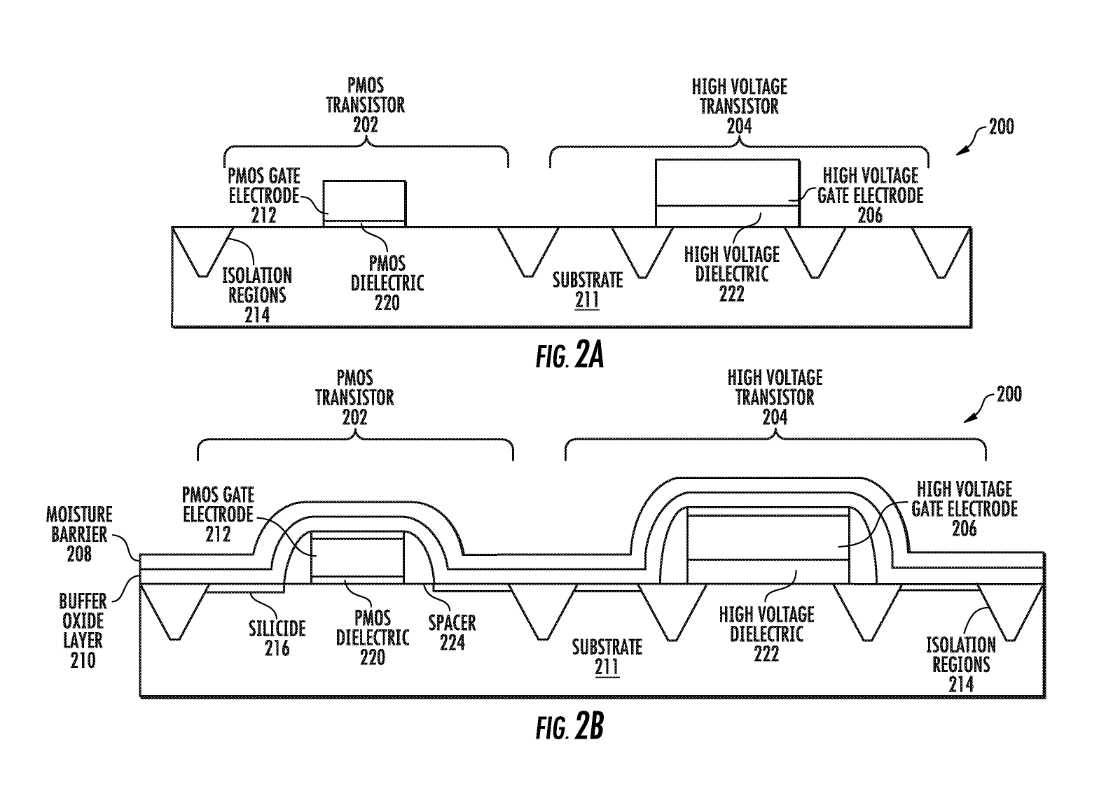

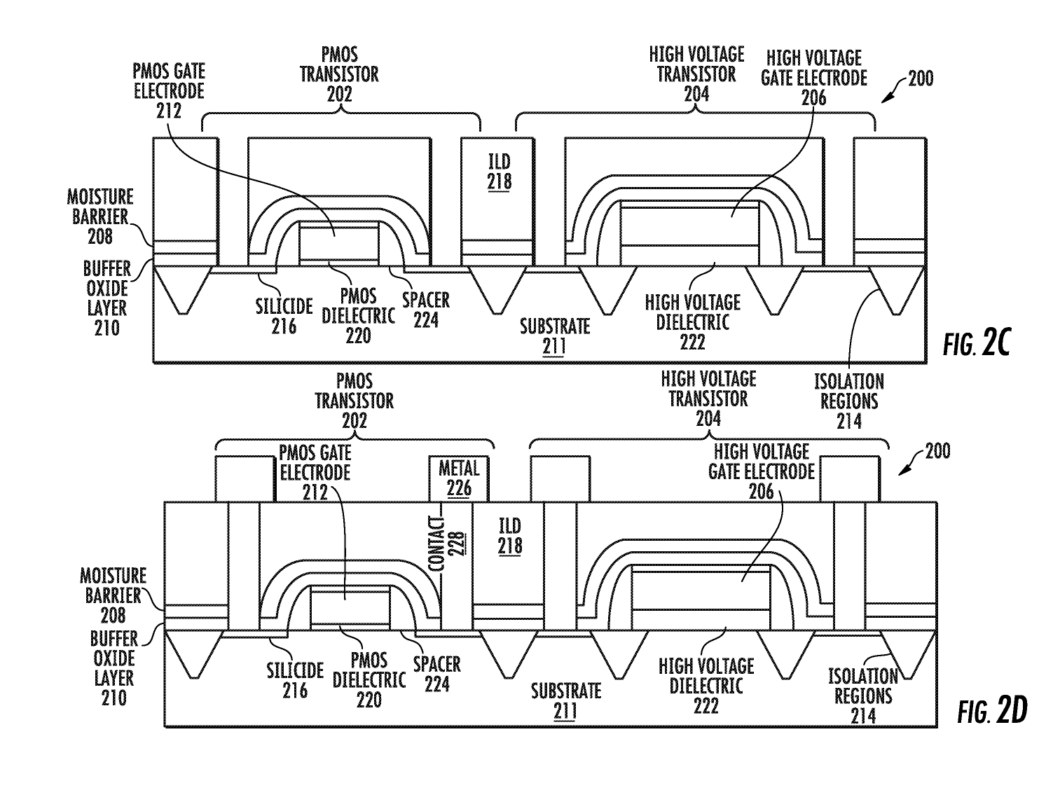

FIGS. 2A-2D illustrate a process for fabricating a semiconductor device 200 having a PMOS transistor 202 and a high voltage transistor 204 with reduced PBTI drift and reduced high voltage gate leakage. FIG. 2A illustrates a semiconductor device 200 when the initial layers of the PMOS transistor 202 and the high voltage transistor 204 are formed on a substrate 211. The initial layers of semiconductor device 200 include PMOS gate electrode 212, PMOS dielectric 220, high voltage gate electrode 206, and high voltage dielectric 222. PMOS gate electrode 212, PMOS dielectric 220, high voltage gate electrode 206, and high voltage dielectric 222 are made from conventional processes for fabricating PMOS and high voltage transistors. For example, a conventional process fabricates PMOS gate electrode 212 and high voltage gate electrode 206 from polysilicon over respective PMOS gate dielectric 220 and high voltage dielectric 222 on substrate 211. Further, the initial layers include isolation regions 214, which are also fabricated from traditional methods. Isolation regions 214 electrically isolate the components of PMOS transistor 202 from the components of high voltage transistor 204.

FIG. 2B illustrates a semiconductor device 200 when a buffer oxide layer 210 and a moisture barrier 208 are deposited onto semiconductor device 200. In certain embodiments of the formation of device 200, before buffer oxide layer 210 is deposited over PMOS gate 212 and high voltage gate 206, spacers 224 are formed next to PMOS gate 212 and high voltage gate 206 according to conventional methods understood in the art. In certain embodiments, after spacers 224 are formed, silicides 216 are formed in the substrate 211 according to traditional methods. For example, silicides 216 are formed to include at least one of cobalt, titanium, and the like.

As shown in FIG. 2B, semiconductor device 200 includes a buffer oxide layer 210 deposited over the top surface of semiconductor device 200. For example, buffer oxide layer 210 is deposited over PMOS transistor 202, high voltage transistor 204, and silicides 216. In certain embodiments, buffer oxide layer 210 is formed, using a plasma-enhanced chemical vapor deposition (PECVD) technique, a low pressure chemical vapor deposition technique (LPCVD), and the like, over the top surface of semiconductor device 200. In one implementation, the fabrication process deposits the PECVD oxide using silane (SiH₄) or tetraethyl orthosilicate (TEOS).

In a further embodiment, semiconductor device 200 includes a moisture barrier 208 that is formed over the top surface of buffer oxide layer 210 on semiconductor device 200. When moisture barrier 208 is formed on buffer oxide layer 210, a PECVD silicon oxynitride (SiON) is deposited over the top surface of buffer oxide layer 210. In some implementations, a plasma process deposits the PECVD silicon oxynitride using a combination of SiH₄, NH₃, N₂O, or other similarly suitable chemicals. When buffer oxide layer 210 and moisture barrier 208 are formed, the remaining layers of semiconductor device 200 are fabricated according to standard fabrication processes for semiconductor devices, further explained below in relation to FIGS. 2C and 2D.

In the present example of a semiconductor device 200, semiconductor device 200 includes moisture barrier 208 to reduce PBTI drift. However, the inclusion of the moisture barrier induces stress in semiconductor device 200 which exacerbates leakage currents. To relieve the stress caused by moisture barrier 208, semiconductor device 200 also includes buffer oxide layer 210. The thickness of moisture barrier 208 and buffer oxide layer 210 is determined based on a balancing of the ability of moisture barrier 208 to reduce PBTI drift and the ability of buffer oxide layer 210 to relieve stress. The ability of moisture barrier 208 to reduce PBTI drift increases in direct proportion to the thickness of moisture barrier 208. However, the stress induced by moisture barrier 208 on semiconductor device 200 also increases in direct proportion to the thickness of moisture barrier. To compensate for the increased stress due to an increase in the thickness of moisture barrier 208, the thickness of buffer oxide layer 210 is likewise increased. However, the ability of the buffer oxide layer 210 to effectively relieve stress caused by moisture barrier 208 plateaus as the thickness of buffer oxide layer 210 is increased. When the ability to relieve stress plateaus, the buffer oxide layer 210 becomes less effective at compensating stress induced by increasingly thicker moisture barriers. Due to the plateau in the ability of the buffer oxide layer 210 to relieve stress, the thickness of the moisture barrier 208 is increased only to a thickness in which the buffer oxide layer 210 can effectively relieve stress induced by the buffer oxide layer 210. For example, in some implementations, the ability of buffer oxide layer 210 to relieve stress caused by moisture barrier 210 plateaus at a thickness of 600 angstroms. A buffer oxide layer 210 having a thickness of 600 angstroms effectively reduces the stress induced by moisture barrier 208 having a thickness of 400 angstroms. As such, in some exemplary embodiments, moisture barrier 208 has a thickness between 300 and 1000 angstroms and buffer oxide layer 210 has a thickness greater than 200 angstroms.

FIG. 2C illustrates semiconductor device 200 when the interlayer dielectric (ILD) 218 and contact holes are formed. Silicides 216 are formed in substrate 211 to improve electrical connections between metal and substrate 211. In one embodiment, ILD 218 is deposited over moisture barrier 208. In some implementations, ILD 218 is a Ml/poly-dielectric that includes a thick TEOS oxide film. When ILD 218 is deposited, ILD 218 is polished to achieve a desired thickness for semiconductor device 200. When, the desired thickness is achieved, contact holes are formed through ILD 218, moisture barrier 208, and buffer oxide layer 210 to expose silicides 216. For example, patterns are applied to the top surface of ILD 218 then ILD 218, moisture barrier 208, and buffer oxide layer 210 are etched according to the applied patterns for a sufficient time to expose suicides 216. The amount of etch time is adjustable according to the thickness of ILD 218, moisture barrier 208, and buffer oxide layer 210.

FIG. 2D illustrates semiconductor device 200 when contacts 228 and metal terminals 226 are formed. When the contact holes are formed, metal is deposited into the contact holes to form contacts 228. The deposited metal includes tungsten, aluminum, Titanium, TiN, and the like. After the contacts are formed, the process forms metal terminals 226 according to normal metallization processes.

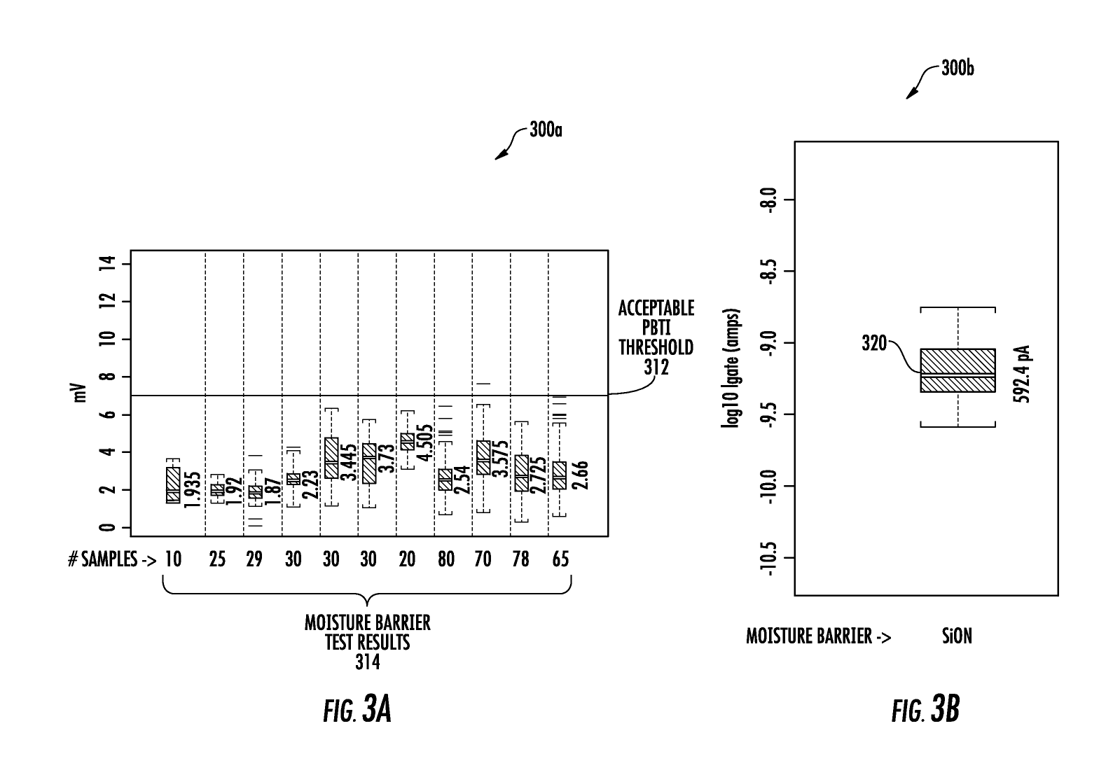

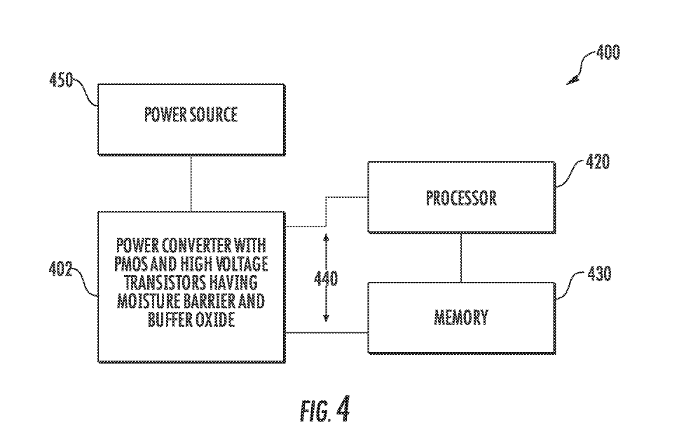

FIG. 3A is a chart 300a showing that PBTI drift is below an acceptable PBTI threshold 312 when a moisture barrier is included in the PMOS transistor. In chart 300a, change in threshold voltage is plotted on the Y-axis. Each column along the X-axis represents a lot of devices fabricated using a particular process. For each lot, the range of threshold voltage change is represented by the rectangle in the particular column. Each lot represented in chart 300a was fabricated using a moisture barrier 108 of SiON. As can be seen, moisture barrier test results 314 show that each of these lots exhibited a change that was below the acceptable PBTI threshold 312, where the acceptable PBTI threshold 312 is 7 mV.

FIG. 3B is a graph 300b that illustrates gate leakage current for high voltage NMOS transistor arrays with a moisture barrier that includes SiON. SiON films induce stress within the transistor, and in some implementations, this stress can exacerbate leakage currents to unacceptable levels. Bar 320 represents gate leakage results of a high voltage NMOS transistor array with a moisture barrier formed from SiON. While, a moisture barrier of SiON exacerbates gate leakage, the moisture barrier of SiON offers a compromise between PBTI and leakage current. For example, in this embodiment, the leakage current is between 200 and 2000 pA. Further, a stress relief buffer oxide layer 110 affects the leakage current of a high voltage transistor. The buffer oxide layer 110 is disposed under the moisture barrier 108 (e.g., SiON). Buffer oxide layer 110 limits the gate leakage current such that the addition of buffer oxide layer 110 maintains the gate leakage current within operational limits.

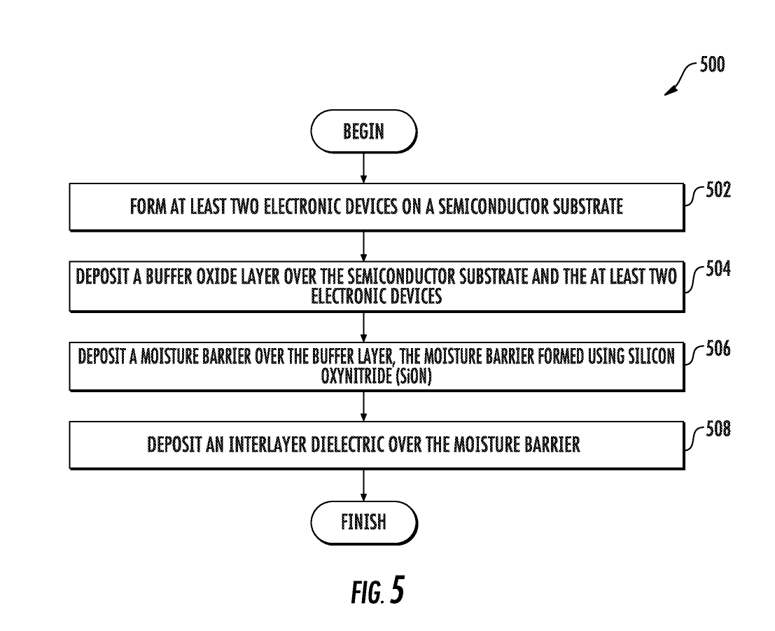

FIG. 4 is a block diagram of an embodiment of an electronic system 400 with a power converter 402 that includes PMOS and high voltage transistors having a moisture barrier and a buffer oxide layer such as described in the foregoing embodiments. Power converter 402 receives power from power source 450, where power converter 402 is electrically coupled to at least one processor 420 and at least one memory 430. For example, a bus 440 can provide electrical connections between power converter 402, processor 420, and memory 430. Processor 420 and memory 430 are also electrically coupled to each other. Processor and memory, in one embodiment function as part of a notebook, tablet, or desktop computer. In other embodiments, processor and memory can operate in devices such as embedded systems, computer networks, and the like.

FIG. 5 is a flow diagram illustrating an exemplary method 500 for fabricating a PMOS and high voltage transistor on the same substrate with reduced PBTI drift and reduced gate leakage. Method 500 begins at 502 where at least two electronic devices on a semiconductor substrate are formed. Further, the at least two electronic devices differ from one another in at least one characteristic. For example, a PMOS transistor and a high voltage transistor are formed on a semiconductor substrate. At 504, a buffer oxide layer is deposited over the semiconductor substrate and the at least two electronic devices. At 506, a moisture barrier is deposited over the buffer layer, the moisture barrier formed using silicon oxynitride. At 508, an interlayer dielectric is deposited over the moisture barrier.

Terms of relative position as used in this application are defined based on a plane parallel to the conventional plane or working surface of a wafer or substrate, regardless of the orientation of the wafer or substrate. The term “horizontal” or “lateral” as used in this application is defined as a plane parallel to the conventional plane or working surface of a wafer or substrate, regardless of the orientation of the wafer or substrate. The term “vertical” refers to a direction perpendicular to the horizontal. Terms such as “on,” “side” (as in “sidewall”), “higher,” “lower,” “over,” “top,” and “under” are defined with respect to the conventional plane or working surface being on the top surface of the wafer or substrate, regardless of the orientation of the wafer or substrate.

Although specific embodiments have been illustrated and described herein, it will be appreciated by those of ordinary skill in the art that any arrangement, which is calculated to achieve the same purpose, may be substituted for the specific embodiments shown. Therefore, it is manifestly intended that this invention be limited only by the claims and the equivalents thereof.

What is claimed is:

1. A semiconductor device, comprising:
at least one p-channel, field effect transistor (PFET) device on a semiconductor substrate;
at least one high voltage transistor on the semiconductor substrate;
a buffer oxide layer formed over the semiconductor substrate, the at least one PFET device, and the high voltage transistor; and
a moisture barrier formed over the buffer layer, the moisture barrier composed of silicon oxynitride (SiON).

2. The semiconductor device of claim 1, wherein the buffer oxide layer comprises a layer of silicon dioxide.

3. The semiconductor device of claim 1, wherein the buffer oxide layer has a thickness greater than 200 angstroms.

4. The semiconductor device of claim 1, wherein the moisture barrier has a thickness between 300 and 1000 angstroms.

5. The semiconductor device of claim 1, further comprising an interlayer dielectric deposited over the moisture barrier.

6. The semiconductor device of claim 5, further comprising at least one electrical contact extending through the interlayer dielectric, the moisture barrier, and the buffer oxide layer, wherein the at least one electrical contact is electrically connected to a silicide.

7. The semiconductor device of claim 1, wherein the at least one high voltage transistor is proximate on the substrate to the at least one PFET device.

8. The semiconductor device of claim 1, wherein the buffer oxide layer is deposited over diffusion and silicides.

9. A method for fabricating a semiconductor circuit, the method comprising:
forming at least two electronic devices on a semiconductor substrate, wherein the at least two electronic devices differ from one another in at least one characteristic;
depositing a buffer oxide layer over the semiconductor substrate and the at least two electronic devices;
depositing a moisture barrier over the buffer layer, the moisture barrier composed of silicon oxynitride (SiON);
depositing an interlayer dielectric over the moisture barrier.

10. The method of claim 9, wherein the at least two electronic devices comprise:
a first device, wherein the first device is a p-channel field effect transistor (PFET) device; and
a second device wherein the second device is a high voltage transistor.

11. The method of claim 9, wherein the moisture barrier is deposited at a thickness that allows the buffer oxide layer to compensate for the increase in high voltage gate leakage current caused by the moisture barrier.

12. The method of claim 9, wherein the buffer oxide layer, having a thickness greater than 200 angstroms compensates for the increase in gate leakage current caused by the moisture barrier.

13. The method of claim 9, wherein the moisture barrier has a thickness between 300 and 1000 angstroms.

14. The method of claim 9, wherein depositing a buffer oxide layer comprises using a plasma-enhanced chemical vapor deposition (PECVD) of oxide.

15. The method of claim 14, wherein, the PECVD of oxide uses at least one of SiH₄, and TEOS.

16. The method of claim 9, wherein depositing a moisture barrier comprises using a PECVD silicon oxynitride using SiH₄, NH₃, and N₂O.

17. The method of claim 9, wherein forming an electrical contact comprises etching through the interlayer dielectric, the moisture barrier, and the buffer oxide layer to expose a portion of the semiconductor substrate.

18. The method of claim 17, wherein the portion of the semiconductor substrate comprises a silicide.

19. The method of claim 17, further comprising:
determining an etch time based on a interlevel dielectric thickness, a moisture barrier thickness, and a buffer oxide layer thickness.

20. The method of claim 9, wherein the electrical contacts are composed of at least one of:
tungsten;
titanium; and
aluminum.

21. The method of claim 9, further comprising polishing the interlayer dielectric to achieve a desired thickness of the semiconductor device.

22. An electrical device, comprising:
at least one p-channel, field effect transistor (PFET) device on a semiconductor substrate;
at least one high voltage transistor on the semiconductor substrate;
a plurality of silicides formed in the semiconductor substrate, the plurality of silicides formed proximate to the at least one PFET device and the at least one high voltage transistor;
a buffer oxide layer formed over the semiconductor substrate, the at least one PFET device, and the at least one high voltage transistor;
a moisture barrier formed over the buffer layer, the moisture barrier comprised of silicon oxynitride (SiON);
an interlayer dielectric device formed over the moisture barrier; and
a plurality of electrical contacts extending through the interlayer dielectric, the moisture barrier, and the buffer oxide layer, wherein the plurality of electrical contacts are electrically connected to the plurality of silicides.

23. The semiconductor device of claim 22, wherein the buffer oxide layer comprises a layer of silicon dioxide.

24. The semiconductor device of claim 22, wherein the at least one high voltage transistor is proximate on the substrate to the at least one PFET device.

25. An electronic system, comprising:
a processor;
at least one memory device, coupled to the processor; and
a power converter coupled to the processor and the at least one memory device, the power converter comprising:
a plurality of devices formed on the semiconductor substrate, wherein devices in the plurality of devices are configured to perform different functions;
a buffer oxide layer formed over the plurality of devices and the semiconductor substrate; and
a moisture barrier formed over the buffer layer, the moisture barrier comprised of silicon oxynitride (SiON).
